(19) United States
(12) Patent Application Publication
(10) Pub. No.: US 2013/0223646 A1
(43) Pub. Date: Aug. 29, 2013

(54) SPEAKER CONTROL METHOD AND SPEAKER CONTROL SYSTEM

(71) Applicants: Chuan-Fu Lee, New Taipei City (TW); Fa-Yu Hsieh, New Taipei City (TW); Wei-Lun Liu, New Taipei City (TW)

(72) Inventors: Chuan-Fu Lee, New Taipei City (TW); Fa-Yu Hsieh, New Taipei City (TW); Wei-Lun Liu, New Taipei City (TW)

(21) Appl. No.: 13/441,911

(22) Filed: Apr. 8, 2012

(30) Foreign Application Priority Data
Feb. 23, 2012 (TW) 101105986

(51) Int. Cl. H04B 15/00; H03F 99/00

(52) U.S. Cl. 381/94.5

(57) ABSTRACT

A speaker control method includes steps of detecting whether there is any audio signal input; outputting a first voltage signal if there is no audio signal input; outputting a second voltage signal if there is an audio signal input; and selectively turning off an audio amplifier according to the first voltage signal or turning on the audio amplifier according to the second voltage signal, wherein the audio amplifier is used for driving a speaker.

### BACKGROUND OF THE INVENTION

1. Field of the Invention

The invention relates to a speaker control method and a speaker control system and, more particularly, to a speaker control method and a speaker control system capable of turning off an audio amplifier when a speaker is idle so as to save power.

2. Description of the Prior Art

So far most of electronic devices are equipped with a speaker for playing audio. The speaker usually works with an audio digital-to-analog converter (audio DAC) and an audio amplifier. The audio DAC is used for converting digital audio signals into analog audio signals and the audio amplifier is used for amplifying analog audio signals and driving the speaker. In general, the speaker is always driven by the audio amplifier to work no matter whether the speaker is idle. In other words, power is still consumed by the speaker even if the speaker is idle. Furthermore, if the speaker still works during idle state, pop noise may occur and disturb a user when a plug is plugged into an audio port.

### SUMMARY OF THE INVENTION

The invention provides a speaker control method and a speaker control system capable of turning off an audio amplifier when a speaker is idle so as to save power and prevent pop noise from occurring.

According to the claimed invention, a speaker control method comprises steps of detecting whether there is any audio signal input; outputting a first voltage signal if there is no audio signal input; outputting a second voltage signal if there is an audio signal input; and selectively turning off an audio amplifier according to the first voltage signal or turning on the audio amplifier according to the second voltage signal, wherein the audio amplifier is used for driving a speaker.

According to the claimed invention, the speaker control method further comprises steps of beginning to count time when detecting the first voltage signal; and turning off the audio amplifier when continuously detecting the first voltage signal over a predetermined time period.

According to the claimed invention, the speaker control method further comprises steps of continuously detecting whether the first voltage signal is converted into the second voltage signal; and turning on the audio amplifier when the first voltage signal is converted into the second voltage signal.

According to the claimed invention, the audio amplifier is electrically connected to a delay circuit and the speaker control method further comprises step of turning on or off the audio amplifier through the delay circuit.

According to the claimed invention, the first voltage signal is high and the second voltage signal is low.

According to the claimed invention, a speaker control system comprises a speaker; an audio amplifier electrically connected to the speaker and used for driving the speaker; an audio digital-to-analog converter (audio DAC) electrically connected to the audio amplifier, the audio DAC detecting whether there is any audio signal input, outputting a first voltage signal if there is no audio signal input, and outputting a second voltage signal if there is an audio signal input; and a processor electrically connected to the audio amplifier and the audio DAC, the processor selectively turning off the audio amplifier according to the first voltage signal or turning on the audio amplifier according to the second voltage signal.

According to the claimed invention, the processor begins to count time when detecting the first voltage signal and turns off the audio amplifier when continuously detecting the first voltage signal over a predetermined time period.

According to the claimed invention, the processor continuously detects whether the first voltage signal is converted into the second voltage signal and turns on the audio amplifier when the first voltage signal is converted into the second voltage signal.

According to the claimed invention, the speaker control system further comprises a delay circuit, wherein the processor is electrically connected to the audio amplifier through the delay circuit and the processor turns on or off the audio amplifier through the delay circuit.

According to the claimed invention, the first voltage signal is high and the second voltage signal is low.

As mentioned in the above, the audio DAC outputs the first voltage signal (e.g. high) if there is no audio signal input and outputs the second voltage signal (e.g. low) if there is an audio signal input. When the processor continuously detects the first voltage signal over the predetermined time period (e.g. five seconds, ten seconds, etc.), the processor will turn off the audio amplifier. In other words, the audio amplifier will be turned off when there is no audio signal input such that power will not be consumed by the speaker when the speaker is idle so as to save power. Furthermore, since the audio amplifier will be turned off when there is no audio signal input, any pop noise will not occur such that the speaker can be protected well. After turning off the audio amplifier, the processor will continuously detect whether the first voltage signal is converted into the second voltage signal. When the first voltage signal is converted into the second voltage signal, the processor will turn on the audio amplifier such that the audio amplifier can drive the speaker to play audio according to audio signal input. Since the processor is electrically connected to the audio amplifier through the delay circuit, the processor turns on the audio amplifier through the delay circuit so as to de-pop noise.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram illustrating a speaker control system according to an embodiment of the invention.

FIG. 2 is a flowchart illustrating a speaker control method according to an embodiment of the invention.

### DETAILED DESCRIPTION

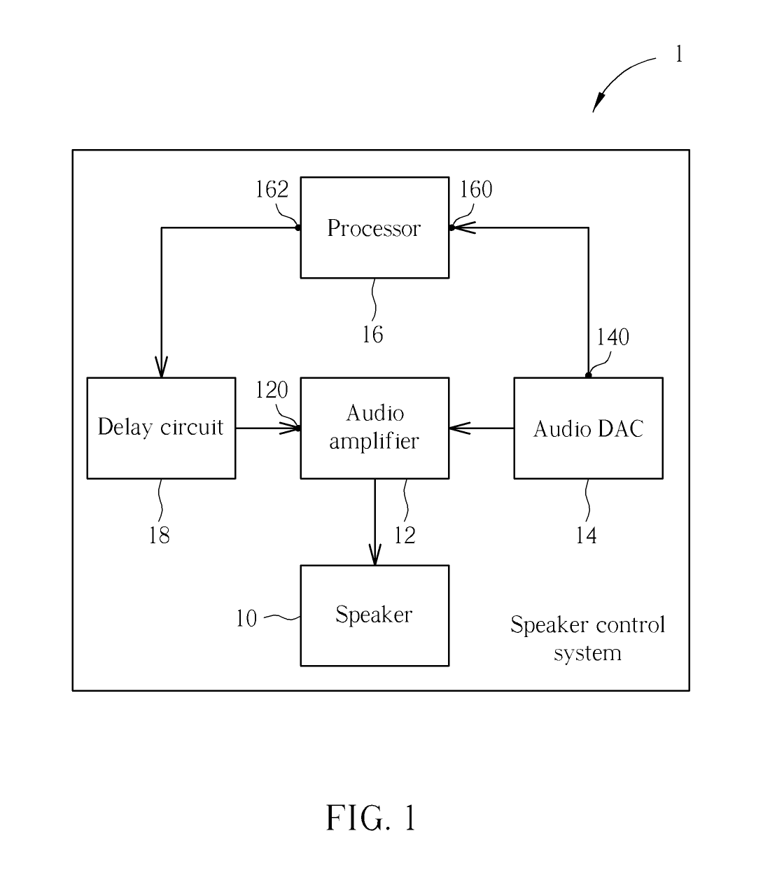

Referring to FIG. 1, FIG. 1 is a functional block diagram illustrating a speaker control system 1 according to an embodiment of the invention. As shown in FIG. 1, the speaker control system 1 comprises a speaker 10, an audio amplifier 12, an audio digital-to-analog converter (audio DAC) 14, a processor 16 and a delay circuit 18, wherein the audio amplifier 12 is electrically connected to the speaker 10, the audio DAC 14 is electrically connected to the audio amplifier 12, and the processor 16 is electrically connected to the audio amplifier 12 through the delay circuit 18 and electrically connected to the audio DAC 14. The audio DAC is used for converting digital audio signals into analog audio signals and the audio amplifier 12 is used for amplifying analog audio signals and driving the speaker 10. In practical applications, the delay circuit 18 may be an RC circuit consisting of resistor(s) and capacitor(s). The speaker control system 1 of the invention can be applied to any electronic devices equipped with a speaker.

In this embodiment, a GPIO4 pin 160 of the processor 16 may be connected to a ZFLAG pin 140 of the audio DAC 14. Furthermore, a GPIO3 pin 162 of the processor 16 may be connected to the delay circuit 18 and the delay circuit 18 may be connected to a shutdown pin 120 of the audio amplifier 12.

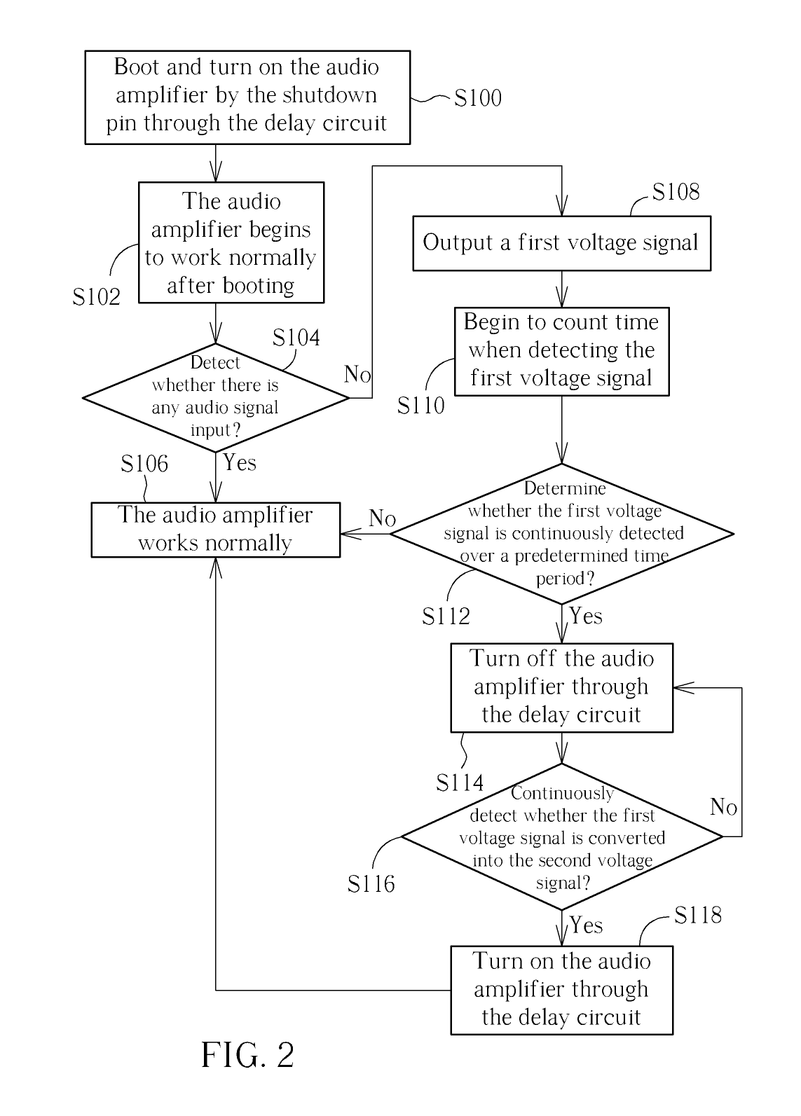

Referring to FIG. 2, FIG. 2 is a flowchart illustrating a speaker control method according to an embodiment of the invention. The speaker control method shown in FIG. 2 can be implemented using the speaker control system 1 shown in FIG. 1. First of all, step S100 is performed to boot and turn on the audio amplifier 12 by the shutdown pin 120 through the delay circuit 18 so as to de-pop noise, wherein a delayed time of the delay circuit 18 can be determined based on practical applications. Afterward, step S102 is performed to release the shutdown pin 120 of the audio amplifier 12 after booting and the GPIO3 pin 162 of the processor 16 is ready so that the audio amplifier 12 begins to work normally. Then, the audio DAC 14 detects whether there is any audio signal input in step S104.

If there is an audio signal input, the audio amplifier 12 works normally in step S106. If there is no audio signal input, the audio DAC 14 outputs a first voltage signal (e.g. high) via the ZFLAG pin 140 in step S108. Afterward, the processor 16 begins to count time when the GPIO4 pin 160 detects the first voltage signal from the ZFLAG pin 140 in step S110. Then, the processor 16 determines whether the GPIO4 pin 160 continuously detects the first voltage signal from the ZFLAG pin 140 over a predetermined time period (e.g. five seconds, ten seconds, etc.) in step S112. For example, step S112 may be implemented by, but not limited to, a software timer built in the processor 16. If the processor 16 does not continuously detect the first voltage signal over the predetermined time period, the audio amplifier 12 continues to work normally in step S106. When the processor 16 continuously detects the first voltage signal over the predetermined time, the GPIO3 pin 162 of the processor 16 outputs high voltage signal to the shutdown pin 120 of the audio amplifier 12 through the delay circuit 18 so as to turn off the audio amplifier 12 in step S114. In other words, the audio amplifier 12 will be turned off when there is no audio signal input such that the speaker 10 will not consume any power during idle state, so as to save power. Furthermore, since the audio amplifier 12 will be turned off when there is no audio signal input, any pop noise will not occur such that the speaker 10 can be protected well.

The aforesaid predetermined time period is used for preventing the audio amplifier 12 from being turned off due to temporary interruption of audio signal input. For example, if a user selects to play several songs successively and an interruption time period between every two songs is three seconds, the aforesaid predetermined time period may be set as five seconds so as to prevent the audio amplifier 12 from being turned off due to temporary interruption of audio signal input.

If the audio DAC 14 detects there is an audio signal input after the processor 16 turns of the audio amplifier 12, the audio DAC 14 will output a second voltage signal (e.g. low) by the ZFLAG pin 140. Accordingly, after the processor 16 turns of the audio amplifier 12, the processor 16 will continuously detect whether the first voltage signal (e.g. high) from the ZFLAG pin 140 of the audio DAC 14 is converted into the second voltage signal (e.g. low) in step S116. When the first voltage signal is converted into the second voltage signal, the GPIO3 pin 162 of the processor 16 will output low voltage signal to the shutdown pin 120 of the audio amplifier 12 through the delay circuit 18 so as to turn on the audio amplifier 12 in step S118 and then return step S106. Afterward, the audio amplifier 12 works normally again to drive the speaker 10 to play audio according to the audio signal input. Since the processor 16 turns on the audio amplifier 12 through the delay circuit 18, the audio amplifier 12 will be turned on after a delayed time period of the delay circuit 18 so as to de-pop noise.

Compared to the prior art, the audio DAC of the invention outputs the first voltage signal (e.g. high) if there is no audio signal input and outputs the second voltage signal (e.g. low) if there is an audio signal input. When the processor continuously detects the first voltage signal over the predetermined time period (e.g. five seconds, ten seconds, etc.), the processor will turn off the audio amplifier. In other words, the audio amplifier will be turned off when there is no audio signal input such that power will not be consumed by the speaker when the speaker is idle so as to save power. Furthermore, since the audio amplifier will be turned off when there is no audio signal input, any pop noise will not occur such that the speaker can be protected well. After turning off the audio amplifier, the processor will continuously detect whether the first voltage signal is converted into the second voltage signal. When the first voltage signal is converted into the second voltage signal, the processor will turn on the audio amplifier such that the audio amplifier can drive the speaker to play audio according to audio signal input. Since the processor is electrically connected to the audio amplifier through the delay circuit, the processor turns on the audio amplifier through the delay circuit so as to de-pop noise.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A speaker control method comprising:
detecting whether there is any audio signal input;
outputting a first voltage signal if there is no audio signal input;
outputting a second voltage signal if there is an audio signal input; and
selectively turning off an audio amplifier according to the first voltage signal or turning on the audio amplifier according to the second voltage signal, wherein the audio amplifier is used for driving a speaker.

2. The speaker control method of claim 1, further comprising:
beginning to count time when detecting the first voltage signal; and
turning off the audio amplifier when continuously detecting the first voltage signal over a predetermined time period.

3. The speaker control method of claim 2, further comprising:
continuously detecting whether the first voltage signal is converted into the second voltage signal; and
turning on the audio amplifier when the first voltage signal is converted into the second voltage signal.

4. The speaker control method of claim 3, wherein the audio amplifier is electrically connected to a delay circuit and the speaker control method further comprises:
turning on or off the audio amplifier through the delay circuit.

5. The speaker control method of claim 1, wherein the first voltage signal is high and the second voltage signal is low.

6. A speaker control system comprising:
a speaker;
an audio amplifier electrically connected to the speaker and used for driving the speaker;
an audio digital-to-analog converter (audio DAC) electrically connected to the audio amplifier, the audio DAC detecting whether there is any audio signal input, outputting a first voltage signal if there is no audio signal input, and outputting a second voltage signal if there is an audio signal input; and
a processor electrically connected to the audio amplifier and the audio DAC, the processor selectively turning off the audio amplifier according to the first voltage signal or turning on the audio amplifier according to the second voltage signal.

7. The speaker control system of claim 6, wherein the processor begins to count time when detecting the first voltage signal and turns off the audio amplifier when continuously detecting the first voltage signal over a predetermined time period.

8. The speaker control system of claim 7, wherein the processor continuously detects whether the first voltage signal is converted into the second voltage signal and turns on the audio amplifier when the first voltage signal is converted into the second voltage signal.

9. The speaker control system of claim 8, further comprising a delay circuit, wherein the processor is electrically connected to the audio amplifier through the delay circuit and the processor turns on or off the audio amplifier through the delay circuit.

10. The speaker control system of claim 6, wherein the first voltage signal is high and the second voltage signal is low.
